(19) United States
(12) Patent Application Publication
(10) Pub. No.: US 2011/0100432 A1
(43) Pub. Date: May 5, 2011

(54) THIN FILM SOLAR CELL AND MANUFACTURING METHOD THEREOF

(75) Inventors: Chiou Fu WANG, Yonghe City (TW); Huo-Hsien CHIANG, Taipei City (TW)

(73) Assignee: DU PONT APOLLO LTD., Pak Shek Kok (HK)

(21) Appl. No.: 12/917,143

(22) Filed: Nov. 1, 2010

Related U.S. Application Data
(60) Provisional application No. 61/257,246, filed on Nov. 2, 2009.

(51) Int. Cl. H01L 31/0224; H01L 31/042; H01L 31/18

(52) U.S. Cl. 136/249; 438/80; 257/E31.124

(57) ABSTRACT

A thin film solar cell and a manufacturing method thereof have been disclosed in the present invention. According to the present invention, the thin film solar cell with an isolation groove can prevent generating short paths between electrodes from occurring.

### FIELD OF THE INVENTION

The present invention is directed to a thin film solar cell and a manufacturing method thereof. In particular, the solar cell has improved effects of isolation.

### BACKGROUND OF THE INVENTION

A solar cell utilizes the conversion of a light energy into an electric energy. The solar cell is formed in a PN-junction, wherein a positive semiconductor (P) makes a junction with a negative semiconductor (N). When a solar cell receives light with the PN-junction structure, holes and electrons are generated in the semiconductor due to the energy of the solar light. The holes are drifted toward the P-type semiconductor, and the electrons are drifted toward the N-type semiconductor in the electric field resulting from the PN-junction area. Consequently, an electric power is produced by the occurrence of electric potential.

As known in the field, the solar cell can be classified into a wafer type solar cell and a thin film solar cell. The wafer solar cell uses a wafer made of a semiconductor material such as silicon, and the thin film solar cell is made by forming a semiconductor in the form of a thin film on a glass substrate.

A monolithic thin film solar cell is manufactured by sequential steps. In a conventional manufacturing process of a thin film solar cell, a front electrode layer is deposited onto a substrate first, then the first electrode layer is laser-scribed, which forms numbers of grooves; a semiconductor layer is subsequently deposited onto the front electrode and then laser-scribed, which forms numbers of grooves; a back electrode is then deposited onto the semiconductor, followed by laser-scribing the back electrode layer and the semiconductor layer, and resulted grooves. By laser-scribing the above-mentioned deposited layers, a thin film solar cell comprised of numbers of unit cells serially connected to each other is obtained.

To prevent problems like short paths and leakage of electrical currents during packaging from occurring, a standard technique of generating an isolation groove can be found in U.S. Pat. No. 6,300,556. Referring to FIG. 1, an isolation groove, 13, is generally produced by laser-scribing or mechanical cuts. In both cases, a short path between electrodes, 2 and 6, can be generated and hence reduce the performance of solar modules. An isolation groove is used to separate the solar cells and the boundaries of the module.

Another application is generating see through solar module or resolving hot spot problem, as shown in U.S. Pat. No. 6,858,461. As shown in FIG. 2, the cut 140 removes only top two layers, top electrode and semiconductor layers. In practical, cutting through all three layers is used as well.

As shown above, a conventional standard technique of creating an isolation groove is by laser-scribing the solar cells after the devices are fabricated. However, parts of the back electrode layer may not be completely removed after laser-scribing due to the variations of temperature in the laser beam, which will lead to residue of the back electrode layer still remain on the front electrode layer, consequently resulting in short paths of electrical currents. In other words, such techniques usually generate random short paths between the front and back electrodes, which would become leakage paths in the solar cells and reduce its performance. Practically, one can monitor such instances by measuring Shunt resistance (Rsh). In addition, the short paths could cause hot spot problem.

In light of the above-mentioned problems, there is a need for a thin film solar cell with an isolation groove which can prevent generating short paths between electrodes from occurring. A thin film solar cell and the manufacturing method thereof have been disclosed in the prevent invention.

### SUMMARY OF THE INVENTION

In some embodiments of the present invention, a thin film solar cell comprises a substrate, a front electrode layer, a semiconductor layer, and a back electrode layer.

In another embodiment of the present invention, a method for manufacturing a thin film solar cell comprises the following steps:

(1) providing a substrate first;

(2) providing a front electrode layer above the substrate;

(3) using a patterning technique to define grooves in the front electrode layer, which divides the front electrode layer into numbers of units, wherein the substrate is exposed at the grooves;

(4) using the patterning technique to form a wide groove with a desired width in the front electrode layer at an isolation area, or using one of the grooves in the front electrode layer as the wide groove, wherein the substrate is exposed at the wide groove and the width of said wide groove is equal to or greater than the width of the grooves in the front electrode layer;

(5) providing a semiconductor layer formed above the front electrode layer;

(6) using a patterning technique to form grooves in the semiconductor layer, which divide the semiconductor layer into numbers of units, wherein the front electrode layer is exposed at the grooves;

(7) providing a back electrode layer formed above the semiconductor layer;

(8) using a patterning technique to form grooves in the back electrode layer or in the back electrode layer and the semiconductor layer, which to divide the back electrode layer into numbers of units, wherein the semiconductor layer or the front electrode layer is exposed at the grooves; and

(9) using the patterning technique at the isolation area above the wide groove to remove layers, which forms an isolation groove extending downward, wherein the substrate is exposed at the isolation groove.

In another embodiment of the present invention, a method for manufacturing a thin film solar cell is provided as well. The method comprises:

(1′) providing a substrate;

(2′) providing a front electrode layer formed above the substrate;

(3′) using a patterning technique to define grooves in the front electrode layer, which divide the front electrode layer into numbers of units, wherein the substrate is exposed at the grooves;

(4′) using the patterning technique to form at least two grooves in the front electrode layer at an isolation area, wherein the distance between each of the at least two grooves is predetermined and the substrate is exposed at the grooves, wherein the distance between each of the at least two grooves is preferably in the range of 0 to 1 cm;

(5′) providing a semiconductor layer formed above the front electrode layer;

(6′) using a patterning technique to form grooves in the semiconductor layer, which divide the semiconductor layer into numbers of units, wherein the front electrode layer is exposed at the grooves;

(7′) providing a back electrode layer formed above the semiconductor layer;

(8′) using a patterning technique to form grooves in the back electrode layer or in the back electrode layer and the semiconductor layer, which divide the semiconductor layer into numbers of units, wherein the semiconductor layer or the front electrode layer is exposed at the grooves; and

(9′) using the patterning technique at the isolation area above the at least two grooves or the region in between two grooves to remove layers, which forms an isolation groove extending downward, wherein the substrate or the front electrode layer is exposed at the isolation groove.

In a further embodiment, the invention is to propose a new method for generating isolation grooves in thin film solar cells with no chance of generating short paths between electrodes, which is easy to carry out and will improve the effects of isolation in the thin film solar cells, thereby preventing the problem of short paths from occurring. Therefore, the performance of the thin film solar cell can be improved. Still further, the occurrence of the hot spot problem can be also reduced by the technique of this invention.

### BRIEF DESCRIPTION OF THE DRAWINGS

The structure and the technical means adopted by the present invention to achieve the above and other objectives can be best understood by referring to the following detailed description of the preferred embodiments and the accompanying diagrams.

FIG. 1 shows a schematic cross sectional view that shows a thin film solar cell in the prior art.

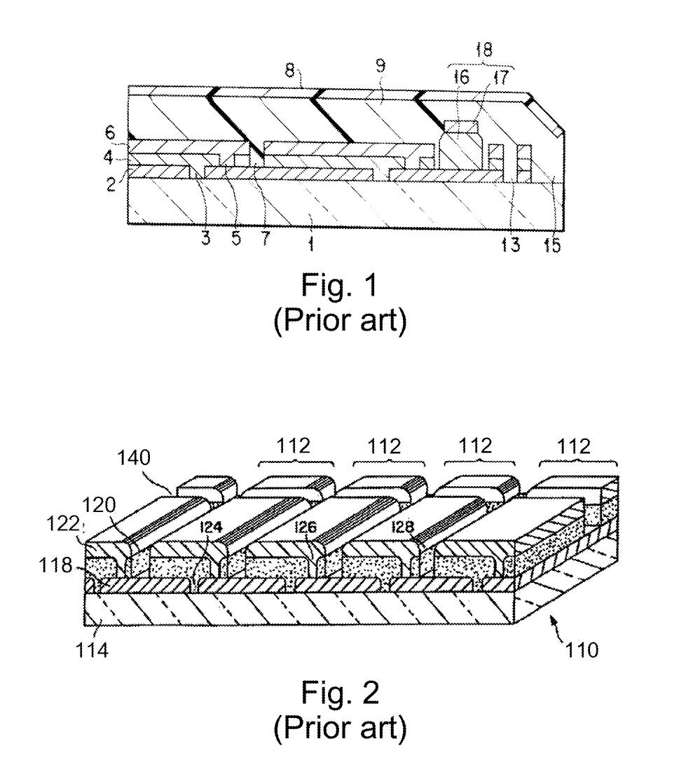

FIG. 2 shows a schematic view that shows a thin film solar cell in the prior art.

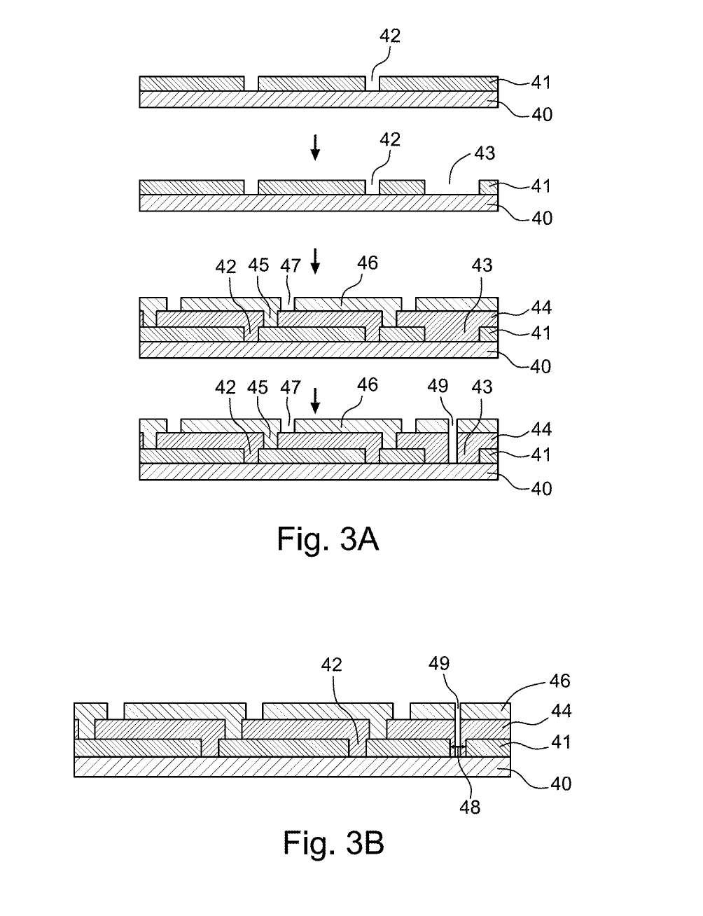

FIGS. 3A and 3B show schematic cross sectional views depicting a process flow of an embodiment of the present invention.

FIGS. 4A to 4C show schematic cross sectional views depicting a process flow of another embodiment of the present invention.

### DETAILED DESCRIPTION OF THE INVENTION

A thin film solar cell and a manufacturing method thereof have been disclosed in the present invention, wherein the methods and principles of photoelectric conversion used in solar cells are well known to persons having ordinary skill in the art, and thus will not be further described hereafter.

For better understanding, the present invention is illustrated below in details by an embodiment with reference to the drawings, which are not intended to limit the scope of the present invention. It will be apparent that any modifications or alterations that can easily be accomplished by those having ordinary skill in the art fall within the scope of the disclosure of the specification.

As well known in the field, the patterning technique used in the present invention can be, but not limited to, laser-scribing, mechanical means, chemical etching, and photolithography. For example, the chemical etching comprises dry etching, wet etching, and etching paste.

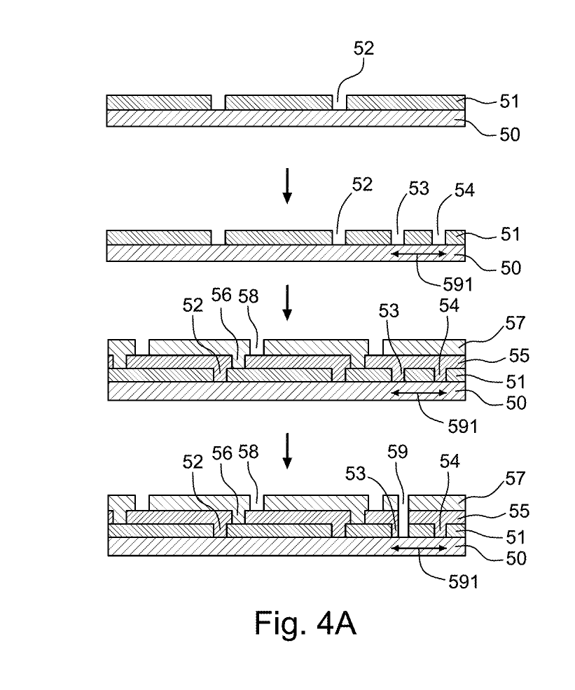

Referring to FIG. 3A, a preferred embodiment is disclosed in the present invention, illustrating a method for manufacturing a thin film solar cell. The method comprises:

(a1) providing a substrate 40;

(a2) providing a front electrode layer 41 formed above the substrate 40;

(a3) laser-scribing the front electrode layer 41 to form a plurality of first grooves 42, which divides the front electrode layer 41 into numbers of units, wherein the substrate is exposed at the first grooves 42;

(a4) laser-scribing the front electrode layer 41 to form a wide groove 43 with a desired width in the front electrode layer at an isolation area, wherein the wide groove 43 has a width greater than that of the first grooves 42 and the substrate is exposed at the wide groove 43;

(a5) providing a semiconductor layer 44 formed above the front electrode layer 41 and the exposed substrate 40;

(a6) laser-scribing the semiconductor layer 44 to form a plurality of second grooves 45, which divides the semiconductor layer 44 into numbers of units, wherein the front electrode layer is exposed at the second grooves 45;

(a7) providing a back electrode layer 46 formed above the semiconductor layer 44 and the exposed front electrode layer 41;

(a8) etching the back electrode layer 46 to form a plurality of third grooves 47, which divides the back electrode layer 46 into numbers of units, wherein the semiconductor layer 44 is exposed at the third grooves 47; and

(a9) laser-scribing the back electrode layer 46 and the semiconductor layer 44 at the wide groove 43 downward, which forms an isolation groove 49 at the isolation area, wherein the substrate 40 is exposed at the isolation groove 49.

In another preferred embodiment which is similar to the above-mentioned embodiment, after steps (a1) to (a7) are performed, a plurality of third grooves 47 can be also defined in the back electrode layer 46 and the semiconductor layer 44 by a patterning technique such as laser-scribing according to the demands (not shown in the figures). Then, the following step is to form an isolation groove 49, which is the same process as the above-mentioned step (a9), and thus will not be further described herein.

In still another preferred embodiment, the first groove can be used as the wide groove. After steps (a1) to (a3), the first grooves 42 are formed. In this embodiment, the width of the (wide) groove is the same as that of one of the grooves. That is, a first groove 42 at an isolation area 48 is used as the wide groove. Then, after step (a4) is skipped and step (a5) is performed, a semiconductor layer 44 is formed above the front electrode layer 41 and the exposed substrate 40. After that, performing steps (a6) to (a8) to form the patterned back electrode. Finally, laser-scribing the back electrode layer 46 and the semiconductor layer 44 at the isolation area above the first groove 42 to form the isolation groove 49 Referring to FIG. 3B, the width of the isolation groove is less than that of the first groove 42.

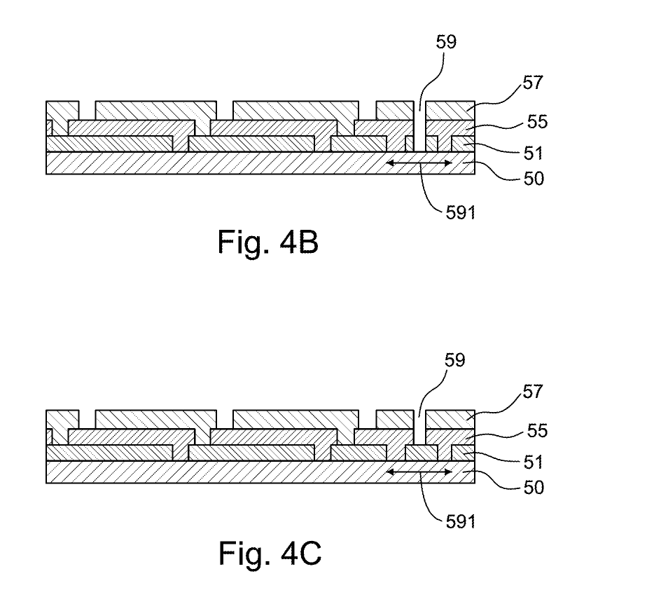

In another preferred embodiment, a method for manufacturing a thin film solar cell is illustrated in FIG. 4A. The method comprises:

(b1) providing a substrate 50;

(b2) providing a front electrode layer 51 formed above the substrate 50;

(b3) laser-scribing the front electrode layer 51 to form a plurality of first grooves 52, which divides the front electrode layer 51 into numbers of units, wherein the substrate 50 is exposed at the first groove 52;

(b4) laser-scribing the front electrode layer 51 at an isolation area 591 to form two grooves 53 and 54 in the front electrode layer 51 at the isolation area, wherein the distance between each of the grooves is predetermined and the substrate is exposed at the grooves 53 and 54;

(b5) providing a semiconductor layer 55 formed above the front electrode layer 51 and the exposed substrate 50;

(b6) laser-scribing the semiconductor layer 55 to form a plurality of second grooves 56, which divides the semiconductor layer 55 into numbers of units, wherein the front electrode layer 51 is exposed at the second grooves 56;

(b7) providing a back electrode layer 57 formed above the semiconductor layer 55 and the exposed front electrode layer 51;

(b8) etching the back electrode layer 57 to form a plurality of third grooves 58, which divides the back electrode layer 57 into numbers of units, wherein the semiconductor layer 55 is exposed at the third grooves 58; and

(b9) laser-scribing the layers within the isolation area 591, which forms an isolation groove 59, wherein the substrate 50 is exposed at the isolation groove 59.

Specifically, referring to FIG. 4A, the laser-scribing is performed at the isolation area 591 of the back layer 57, the semiconductor layer 55 and peripheral portion of the front electrode layer 51 to form the isolation groove 59. Alternatively, referring to FIG. 4B, the laser-scribing could be also performed at the isolation area 591 of the back layer 57, the semiconductor layer 55 and central portion of the front electrode layer 51 to form the isolation groove 59. Alternatively, referring to FIG. 4C, the laser-scribing is performed at within the isolation area 591 of the back layer 57 and the semiconductor layer 55 to form the isolation groove 59. In other words, the laser-scribing can be performed in two layers or three layers at the isolation area 591 according to the demands. In this embodiment, a better position tolerance on scribing the back electrode layer to form the isolation groove 59 is obtained due to the isolation groove 59 could be defined within the isolation area 591.

In another preferred embodiment which is similar to the above-mentioned embodiment, after steps (b1) to (b7) are performed, a plurality of third grooves 58 can be also defined in the back electrode layer 57 and the semiconductor layer 55 by a patterning technique such as laser-scribing according to the demands (not shown in the figures). Then, the following step is to form an isolation groove 59, which is the same process as the above-mentioned step (b9), and thus will not be further described herein.

The front electrode layer includes grooves which divide the front electrode into units. The semiconductor layer is formed above the substrate with grooves which divide the semiconductor layer into units after the front electrode is formed. The back electrode layer is then formed above the semiconductor layer with grooves which divide the back electrode layer into units.

After the solar cell is fabricated, an isolation groove is created at the isolation area according to the demands. For example, the isolation groove could be defined at the peripheral part of the solar cell and is extending downward so as the substrate or the front electrode of the solar cell is exposed at the isolation groove.

Furthermore, the use of the isolation groove comprises, but is not limited to, doing edge deletion, hot spot solution, or see through solar panels. For example, when the isolation groove is used for edge deletion, the isolation groove is generally defined right at the periphery of the panels by laser-scribing or mechanical means.

When the grooves are formed in the semiconductor layer, an offset between each of the grooves in the front electrode layer and each of the grooves in the semiconductor layer exists. Similarly, another offset exists between each of the grooves in the semiconductor layer and each of the grooves in the back electrode layer. The offsets in the solar cell are in the range of 0 to 500 μm, preferably in the range of 5 to 500 μm.

Although the present invention has been described with reference to the illustrative embodiment, it should be understood that any modifications or alterations that can easily be accomplished by persons having ordinary skill in the art will fall within the scope of the disclosure of the specification, drawings, and the appended claims.

What is claimed is:

1. A thin film solar cell, comprising a substrate, a front electrode layer, a semiconductor layer, and a back electrode layer, wherein
the front electrode layer formed above the substrate includes a plurality of grooves which divide the front electrode into units;
the semiconductor layer is formed above the front electrode layer with grooves which divide the semiconductor layer into units;
the back electrode layer is formed above the semiconductor layer with grooves which divide the back electrode layer into units;
an isolation groove is defined at an isolation area of the solar cell and is extending downward so as the substrate or the front electrode layer is exposed at the isolation groove.

2. The thin film solar cell of claim 1, wherein an offset exists between each of the grooves in the front electrode layer and each of the grooves in the semiconductor layer, and another offset exists between each of the grooves in the semiconductor layer and each of the grooves in the back electrode layer.

3. The thin film solar cell of claim 2, wherein the offsets are in the range of 0 to 500 μm.

4. The thin film solar cell of claim 3, wherein the offsets are in the range of 5 to 500 μm.

5. The thin film solar cell of claim 1, wherein the isolation groove is for use of doing edge deletion, hot spot solution and see through solar panels.

6. The thin film solar cell of claim 1, wherein the isolation groove is defined at the peripheral part of the solar cell.

7. A method for manufacturing a thin film solar cell, comprising:
(1) providing a substrate;
(2) providing a front electrode layer above a substrate;
(3) using a patterning technique to define grooves in the front electrode layer, which divides the front electrode layer into numbers of units, wherein the substrate is exposed at the grooves;
(4) using the patterning technique to form a wide groove with a desired width in the front electrode layer at an isolation area, or using one of the grooves in the front electrode layer as the wide groove, wherein the substrate is exposed at the wide groove;
(5) providing a semiconductor layer formed above the front electrode layer;
(6) using a patterning technique to form grooves in the semiconductor layer, which divides the semiconductor layer into numbers of units, wherein the front electrode layer is exposed at the grooves;
(7) providing a back electrode layer formed above the semiconductor layer;
(8) using a patterning technique to form grooves in the back electrode layer or in the back electrode layer and the semiconductor layer, which divides the back electrode layer into numbers of units, wherein the semiconductor layer or the front electrode layer is exposed at the grooves; and
(9) using the patterning technique at the isolation area above the wide groove to remove layers, which forms an isolation groove extending downward, wherein the substrate is exposed at the isolation groove.

8. The method of claim 7, wherein the patterning technique comprises laser-scribing, mechanical means, chemical etching, and photolithography.

9. The method of claim 8, wherein the chemical etching comprises dry etching, wet etching and etching paste.

10. The method of claim 8, wherein the patterning technique is laser-scribing.

11. The method of claim 7, the width of said wide groove is equal to or greater than the width of the grooves in the front electrode layer.

12. A method for manufacturing a thin film solar cell, comprising:
(1′) providing a substrate;
(2′) providing a front electrode layer formed above the substrate;
(3′) using a patterning technique to define grooves in the front electrode layer, which divides the front electrode layer into numbers of units, wherein the substrate is exposed at the grooves;
(4′) using the patterning technique to form at least two grooves in the front electrode layer at an isolation area, wherein the distance between each of the at least two grooves is predetermined and the substrate is exposed at the grooves;
(5′) providing a semiconductor layer formed above the front electrode layer;
(6′) using a patterning technique to form grooves in the semiconductor layer, which divides the semiconductor layer into numbers of units, wherein the front electrode layer is exposed at the grooves;
(7′) providing a back electrode layer formed above the semiconductor layer;
(8′) using a patterning technique to form grooves in the back electrode layer or in the back electrode layer and the semiconductor layer, which divides the semiconductor layer into numbers of units, wherein the semiconductor layer or the front electrode layer is exposed at the grooves; and
(9′) using the patterning technique at the isolation area above the at least two grooves or the region in between two grooves to remove layers, which forms an isolation groove extending downward, wherein the substrate or the front electrode layer is exposed at the isolation groove.

13. The method of claim 12, wherein the patterning technique comprises laser-scribing, mechanical means, chemical etching, and photolithography.

14. The method of claim 13, wherein the chemical etching comprises dry etching and wet etching.

15. The method of claim 13, wherein the patterning technique is laser-scribing.

16. The method of claim 12, wherein the distance between each of the at least two grooves is in the range of 0 to 1 cm.
